(19) United States
(12) Patent Application Publication
(10) Pub. No.: US 2005/0200711 A1
(43) Pub. Date: Sep. 15, 2005

(54) Solid state imaging device and manufacturing method thereof

(75) Inventors: Ryu Shimizu, Mizuho-City (JP); Kazuhiro Sasada, Hashima-City (JP); Masahiro Oda, Itami- City (JP)

Correspondence Address: MCDERMOTT WILL & EMERY LLP, 600 13TH STREET, N.W., WASHINGTON, DC, 20005-3096, US

(73) Assignee: Sanyo Electronic Co., Ltd.

(21) Appl. No.: 11/074,863

(22) Filed: Mar. 9, 2005

(30) Foreign Application Priority Data
Mar. 9, 2004 (JP) 2004-066025
Oct. 22, 2004 (JP) 2004-308461

(51) Int. Cl. H04N 5/225

(52) U.S. Cl. 348/207.99

(57) ABSTRACT

A solid state imaging device includes photoelectric conversion portions for performing photoelectric conversion, and transfer portions for transferring signal charge occurring at the photoelectric conversion portions. Each transfer portion includes a transfer electrode formed of polysilicon film or the like, and an insulating coating film formed of a material such as a silicon nitride film and so forth, which has a higher relative dielectric constant than that of the silicon oxide, for coating the bottom face, the upper face, and both side faces, of the transfer electrode. The silicon nitride film is formed with a film thickness which is greater than 0 nm and smaller than 60 nm, on both sides of the transfer electrode.

### BACKGROUND OF THE INVENTION

1. Field of the Invention

The present invention relates to a solid state imaging device and a manufacturing method thereof.

2. Description of the Related Art

In recent years, development of a solid state imaging device is being intensely undertaken, which has a layer structure wherein the upper face, the bottom face, or both the upper and bottom faces, of each transfer electrode formed of polysilicon are coated with a silicon nitride film, for improving the sensitivity of the solid state imaging device such as a CCD image sensor (which will be abbreviated to as “CCD” hereafter as appropriate).

As this kind of technique, an arrangement described in Japanese Unexamined Patent Application Publication No. 2001-168314 is known. FIG. 3 is a schematic cross-sectional diagram which shows a gate structure of a conventional solid state imaging device described in Japanese Unexamined Patent Application Publication No. 2001-168314.

A gate structure 200 described in Japanese Unexamined Patent Application Publication No. 2001-168314 has a cross-sectional structure wherein a silicon oxide film 206, a silicon nitride film 202, a polysilicon film 204, and a silicon nitride film 202, are layered in that order on a silicon substrate 208.

Such a structure enables a high-performance solid state imaging device having advantages of high sensitivity, high transmission performance, low dark current, and so forth, at the same time, as described in Japanese Unexamined Patent Application Publication No. 2001-168314.

FIGS. 4A through 4E are a series of cross-sectional diagrams which shows an example of the gate structure of a conventional solid state imaging device for each manufacturing step.

First, as shown in FIG. 4A, the silicon oxide film 206 is formed on the silicon substrate 208. Subsequently, as shown in FIG. 4B, a silicon nitride film 202a, the polysilicon film 204, and a silicon nitride film 202b, are layered on the silicon oxide film 206 in that order.

Furthermore, as shown in FIG. 4C, a resist film 210 is formed on a silicon nitride film 202b. Then, as shown in FIG. 4D, etching of the silicon oxide film 206, the silicon nitride 202a, the polysilicon film 204, and the silicon nitride film 202b, is performed.

Subsequently, as shown in FIG. 4E, the resist film 210 is removed by etching, whereby the gate structure 200 shown in FIG. 3 is obtained.

In general, further steps such as etching step and so forth are performed for forming other components of the solid state imaging device.

Note that, in general, the gate structure 200 having such a three-layer structure of silicon nitride film/polysilicon film/silicon nitride film is coated with an insulating film with a low refractive index such as a silicon oxide film and so forth.

In general, there is a correlation between the relative dielectric constant and the refractive index, wherein an insulating film with a low refractive index formed of an ordinary material such as silicon oxide exhibits a low relative dielectric constant. Accordingly, in some cases, a charge transfer device such as a CCD having an electrode structure wherein each electrode is coated with an insulating film with a low refractive index such as a silicon oxide film and so forth has a problem of an insufficient charge which can be stored in each electrode structure.

Also, in some cases, the solid state imaging device having such a three-layer electrode structure of silicon nitride film/polysilicon film/silicon nitride film has a problem of great irregularities in the resistance of the transfer electrode, leading to low yield.

### SUMMARY OF THE INVENTION

The present invention has been made in view of the above problems, and accordingly, it is an object thereof to provide a solid state imaging device exhibiting excellent charge-accumulation performance. Furthermore, it is another object of the present invention to provide a solid state imaging device including transfer electrodes having excellent electro-conductivity, with stable yield in manufacturing.

A solid state imaging device according to a first aspect of the present invention comprises: photoelectric conversion portions for performing photoelectric conversion; and transfer portions for transferring signal charge occurring at the photoelectric conversion portion, with each of the transfer portion including a transfer electrode, and an insulating coating film formed of a material having a higher relative dielectric constant than that of silicon oxide, for coating the bottom face, the upper face, and both side faces, of the transfer electrode.

With such a structure, the bottom face, the upper face, and both side faces, of each transfer electrode, are coated with an insulating coating film formed of a material having a higher relative dielectric constant than that of silicon oxide, and accordingly, a charge is readily induced near the transfer electrode, thereby increasing the charge which can be accumulated in each transfer portion including the transfer electrode. Furthermore, such structure suppresses irregularities in the width of the transfer electrode of the solid state imaging device.

Furthermore, an arrangement may be made wherein the insulating coating film may has a refractive index which is greater than that of silicon oxide, and smaller than that of the transfer electrode. With such a structure, the incident light passes through the regions of a small refractive index, a middle refractive index, and a large refractive index, in that order, whereby the incident light passes through the structure without rapid change in the refractive index. This suppresses reflection of the incident light which passes through the insulating coating film and the transfer electrode. The insulating coating film may be formed of a material containing silicon nitride. Also, the insulating coating film may be formed of a material containing silicon oxynitride. The transfer electrode may be formed of a material containing polysilicon.

Furthermore, an arrangement may be made wherein the insulating coating film is formed with a film thickness t in a range of 0 nm<t<60 nm, on both side faces of the transfer electrode. The aforementioned structure wherein the insulating coating film is formed with a film thickness t in a range of 0 nm<t<60 nm is an ideal structure exactly as designed, and it should be understood that the present invention also encompasses structures wherein the insulating coating film is formed with a film thickness outside of the aforementioned ideal range, i.e., the range of 0 nm<t<60 nm, due to irregularities in the manufacturing process. The capacitance between the transfer electrode and the semiconductor substrate including an insulating coating film with a film thickness in the aforementioned range on both side faces thereof is greater than the capacitance between the transfer electrode and the semiconductor substrate including no insulating coating film on both side faces thereof. Thus, such a structure increases the number of saturation electrons which can be accumulated and transferred within the semiconductor substrate.

Furthermore, an arrangement may be made wherein the multiple transfer portions are arrayed in parallel, with an insulating film, which has a lower relative dielectric constant than that of the insulating coating film, introduced therebetween. Such a structure improves the charge transfer efficiency even with an arrangement including a great number of photoelectric conversion portions. Furthermore, the multiple transfer portions may be arrayed in parallel, with an insulating film having a lower refractive index than that of the insulating coating film, introduced therebetween. Such a structure reduces reflection of the incident light at any incident angle regardless of whether perpendicular or slant incident angle; the incident light being cast onto the transfer portion. Such a structure may be applied to an arrangement wherein each transfer portion includes a photoelectric conversion portion thereunder, thereby improving the sensitivity of each photoelectric portion with regard to the light.

A manufacturing method for a solid state imaging device according to a second aspect of the present invention comprises: a step wherein a first insulating coating film formed of a material having a higher relative dielectric constant than that of silicon oxide, an electro-conductive film, and a second insulating coating film formed of a material having a higher relative dielectric constant than that of silicon oxide, are layered in that order on the upper face of a semiconductor substrate, thereby forming a multi-layer structure; a step for performing selective etching of the multi-layer structure with a predetermined width; a step for forming a third insulating coating film formed of a material having a higher relative dielectric constant than that of silicon oxide, so as to cover the upper face, both side faces, of the multi-layer structure, and the upper face of the semiconductor substrate; and a step for etching the third insulating coating film such that both faces of the multi-layer structure are covered with the third insulating coating film thus patterned.

With the aforementioned method, a solid state imaging device is obtained, which includes an electrode structure wherein the bottom face, the upper face, and both side faces, of each transfer electrode, are coated with an insulating coating film formed of a material having a higher relative dielectric constant than that of silicon oxide, and accordingly, the charge is readily induced near the transfer electrode, thereby increasing the charge which can be accumulated within each transfer portion including the transfer electrode. Furthermore, with such a method, a solid state imaging device is obtained, which includes an electrode structure wherein the bottom face, the upper face, and both side faces, of each transfer electrode, are coated with an insulating coating film. Thus, such a method has the advantage of protecting each transfer electrode from an etchant by the insulating coating film at the time of further etching processing for other portions of the solid state imaging device following formation of the transfer electrodes. This suppresses irregularities in the width of the transfer electrodes of the solid state imaging device, thereby suppressing increase of the resistance of the transfer electrode due to reduction of the cross-sectional area thereof.

### BRIEF DESCRIPTION OF THE DRAWINGS

FIG. 1 is a schematic cross-sectional diagram which shows a gate structure of a solid state imaging device according to a first embodiment;

FIGS. 2A through 2E are a series of cross-sectional diagrams, which shows an example of the gate structure of the solid state imaging device according to the second embodiment for each manufacturing step;

FIG. 3 is a schematic cross-sectional diagram which shows a gate structure of a conventional solid state imaging device;

FIGS. 4A through 4E are a series of cross-sectional diagrams which shows an example of the gate structure of a conventional solid state imaging device for each manufacturing step;

FIGS. 5F and 5G are a series of cross-sectional diagrams, which shows the problem of the gate structure of a conventional solid state imaging device, showing the gate structure for each of the manufacturing steps;

FIG. 6 is an enlarged cross-sectional diagram which shows the problems of a gate structure of a conventional solid state imaging device;

FIG. 7 is a cross-sectional diagram for describing an arrangement wherein SiN is embedded in the gap in the gate structure of the conventional solid state imaging device, which has occurred due to erosion;

FIG. 8 is a cross-sectional diagram for describing an arrangement wherein SiO₂ is embedded in the gap in the gate structure of the conventional solid state imaging device, which has occurred due to erosion;

FIG. 9 is a cross-sectional diagram which shows an modification of a gate structure of a solid state imaging device according to a third embodiment;

FIG. 10 is a cross-sectional diagram which shows an modification of a gate structure of a solid state imaging device according to a fourth embodiment;

FIG. 11 is a cross-sectional diagram which shows an modification of a gate structure of a solid state imaging device according to a fifth embodiment;

FIGS. 12A and 12B are cross-sectional diagrams which show reflection of the incident light with a gate structure of a conventional solid state imaging device serving as a comparative example, and reflection thereof with the gate structure of the solid state imaging device according to the first embodiment, respectively;

FIG. 13 is a cross-sectional diagram which shows the transfer portions and the photoelectric conversion portions of a solid state imaging device according to a seventh embodiment;

FIG. 14 is an overall plan view of the solid state imaging device according to the seventh embodiment;

FIG. 15 shows the relation between the film thickness of the silicon nitride film formed on the side face of the polysilicon film and the number of the saturation electrons which can be accumulated and transferred within the silicon substrate underneath the silicon oxide film, with regard to the solid state imaging device according to the first embodiment, obtained by simulation;

FIGS. 16A and 16B show the conditions of the simulation shown in FIG. 15; and

FIGS. 17A through 17C are diagrams which show the relation between: the film thickness of the silicon nitride film formed on the side face of the polysilicon film of the solid state imaging device according to the first embodiment; and each of the electrode-substrate capacitance, the electrode-electrode capacitance, and the electrode-substrate capacitance with a structure including the single electrode alone.

### DETAILED DESCRIPTION OF THE INVENTION

Description will be made regarding embodiments according to the present invention with reference to the drawings. Note that the same components are denoted by the same reference numerals in all the drawings, and description thereof will be omitted as appropriate.

### First Embodiment

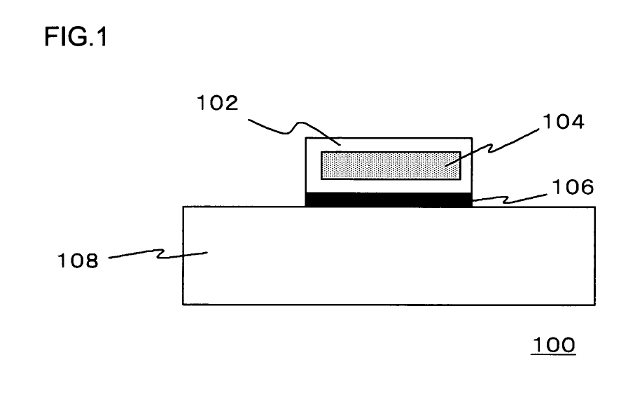

FIG. 1 is a schematic cross-sectional diagram which shows a gate structure of a solid state imaging device according to the present embodiment. A gate structure 100 according to the present embodiment includes: a silicon substrate 108; a silicon oxide film 106 formed on the silicon substrate 108; and a polysilicon film 104 formed on the silicon oxide film 106. Each of the upper face, the bottom face, and both side faces, of the polysilicon film 104 are coated with a silicon nitride film 102.

The polysilicon film 104 serves as a transfer electrode of the solid state imaging device. The silicon nitride film 102 serves as an insulating coating film for coating the bottom face, the upper face, and both side faces, of the transfer electrode. The silicon oxide film 106 serves as a gate insulating film. The silicon substrate 108 serves as a semiconductor substrate. The gate structure 100 including the aforementioned components forms a transfer portion of the solid state imaging device.

The solid state imaging device including the gate structure 100 according to the present embodiment may be a charge-coupled device (CCD) and so forth. The CCD is a device having a mechanism wherein charge is transferred in a semiconductor substrate using a clock pulse signal applied to electroconductive electrodes.

The aforementioned CCD may be a frame-transfer CCD. The frame-transfer CCD has a function wherein photoelectric conversion occurs at a photoelectric conversion portion in the semiconductor substrate due to the light passing through a transfer portion having a function of charge transfer.

With the frame-transfer CCD, the photoelectric conversion portion (not shown) is formed within the silicon substrate 108. Accordingly, the incident light cast onto the photoelectric conversion portion contains the light passing through the silicon nitride film 102, the polysilicon film 104, and the silicon oxide film 106.

With the solid state imaging device according to the present embodiment, the polysilicon film 104 serving as an electroconductive component of the gate structure 100 is coated with the silicon nitride film 102 serving as an insulating component, forming a structure which protects the polysilicon film 104 from exposure. Such a structure suppresses damage due to the manufacturing process for the solid state imaging device to a minimum.

With the solid state imaging device such as a CCD device, which includes a transfer portion having a MOS electrode structure, the gate structure 100 reduces irregularities in resistance of the transfer electrode.

For example, following formation of the polysilicon film 104 serving as a gate electrode, the polysilicon film 104, which is an electroconductive component, is protected from exposure to chemical liquid, plasma, and so forth, at the time of cleansing, surface treatment, and so forth. This prevents erosion of the polysilicon film 104 which is an electroconductive component, edge roughness thereof, and so forth.

Note that the upper face, the bottom face, and both side faces, of the polysilicon film 104 should be coated with the silicon nitride film 102. That is to say, an arrangement may be made wherein both ends of the polysilicon film 104 are not coated, which allows connection of the transfer electrode to another electroconductive component.

Furthermore, the silicon nitride film 102 may be formed of either a single film or multiple films. The silicon nitride film 102 having a multi-layer structure wherein each of the multiple films are formed of the same material exhibits strong bonding thereof. Such a structure has a function sufficient for preventing the polysilicon film 104 from exposure to chemical liquid, plasma, and so forth, as well.

While description has been made regarding the silicon nitride film 102 having a multi-layer structure wherein each of the multiple films are formed of the same single material, an arrangement may be made wherein, the aforementioned multiple films are formed of multiple kinds of materials. For example, an arrangement may be made wherein part of the multiple films are formed of silicon nitride films, and the other part thereof are formed of silicon oxynitride films. Such a multi-layer structure of the silicon nitride film 102 formed of multiple kinds of materials has a function sufficient for preventing the polysilicon film 104 from exposure to a chemical liquid, plasma, and so forth, as long as the bottom face, the upper face, and both side faces, of the polysilicon film 104 are coated with the silicon nitride film 102. Note that, in general, the multi-layer structure formed of the same single material exhibits strong bonding thereof, thereby suppressing a problem of gap formation between layers thereof.

As described above, the present embodiment employs such an electrode structure wherein the bottom face, the upper face, and both side faces, of the transfer electrode are coated with an insulating coating film, whereby the insulating coating film protects the transfer electrode from exposure to an etchant and so forth, at the time of subsequent steps following formation of the transfer electrode. This suppresses irregularities in the width of the transfer electrodes of the solid state imaging device.

This results in suppressing increase of resistance due to the reduced cross-sectional area of the transfer electrode, thereby enabling stable yield of the solid state imaging devices including the transfer electrodes having excellent electro-conductivity.

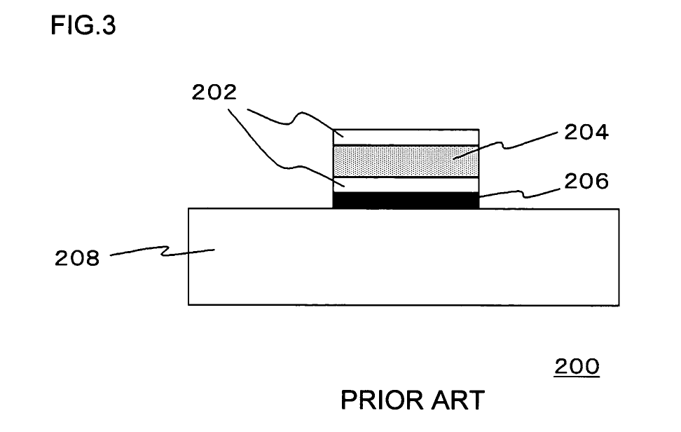

On the other hand, let us say that, following formation of the electrode structure of a three-layer structure of the silicon nitride film 202/polysilicon film 204/silicon nitride film 202 as shown in FIG. 3, the electrode structure is subjected to further etching processing for other portions as described later. In some cases, this causes side etching of the polysilicon portion alone, which is an electro-conductive component, i.e., erosion thereof in the side direction thereof, depending upon the conditions of etching such as the kind of the etchant and so forth.

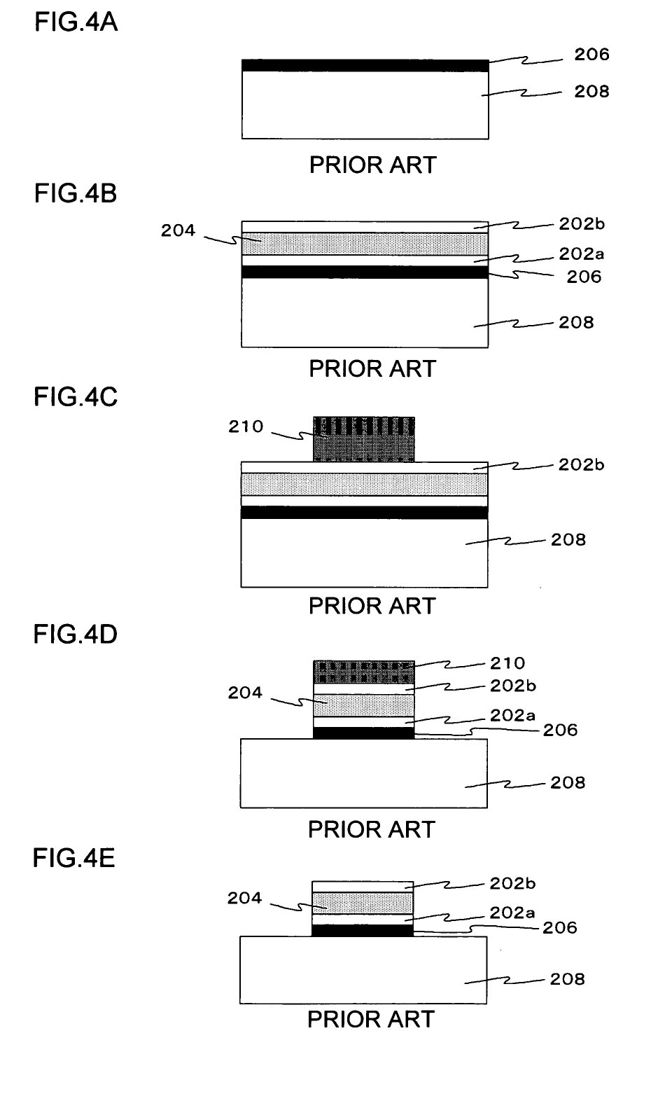

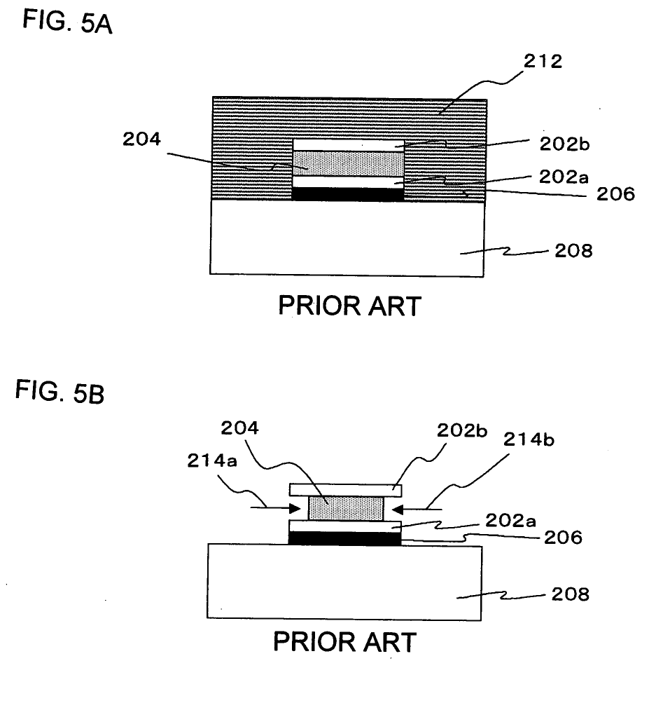

FIGS. 5F and 5G are a series of cross-sectional diagrams, which shows the problem of the gate structure of a conventional solid state imaging device, showing the gate structure for each of the subsequent manufacturing steps. For example, following formation of the gate structure of the conventional solid state imaging device in the manufacturing process shown in FIGS. 4A through 4E as described above, the silicon oxide film 206, the silicon nitride film 202a, the polysilicon film 204, and the silicon nitride film 202b, are coated with a resist film 212, for further etching of other portions (not shown) as shown in FIG. 5F.

Subsequently, etching processing is performed, following which the resist film 212 is removed as shown in FIG. 5G. In some cases, this etching processing causes erosion of the side wall of the polysilicon film 204 in the directions 214a and 214b indicated by the arrows, depending upon the etching conditions such as the kind of the etchant and so forth.

In some cases, this phenomenon leads to reduced width of the polysilicon film 204 which is an electro-conductive component, resulting in increased resistance of the transfer electrode.

Such erosion of the side wall of the polysilicon film 204 often leads to a problem of edge roughness which occurs due to irregularities in the edge of the polysilicon film 204 serving as a transfer electrode. This leads to poor precision of the width of the transfer electrode in manufacturing, resulting in difficulties in realizing and controlling the circuit properties of the CCD exactly as designed.

Furthermore, with a CCD of the type wherein light passes through the gate structure formed on the upper portion of the silicon substrate 208 so as to be introduced into the photoelectric conversion portion formed within the silicon substrate 208, such as a frame-transfer CCD and so forth, the aforementioned edge roughness leads to a problem of irregular reflection of light near the edge of the polysilicon film 204 serving as the transfer electrode, often resulting in noise.

On the other hand, the electrode structure according to the present embodiment shown in FIG. 1 has the gate structure 100 formed such that, at the final stage of the gate manufacturing process, the polysilicon film 104 serving as an electro-conductive component is coated with the silicon nitride film 102 which is an insulating film having a relatively high dielectric constant as compared with the polysilicon film 104. Furthermore, the polysilicon film 104 coated with the silicon nitride film 102 is formed above the silicon substrate 108 with the silicon oxide film 106 introduced therebetween. Note that the silicon oxide film 106 has a relatively low dielectric constant as compared with the silicon nitride film 102.

Such a gate structure results in increased capacitance around the polysilicon film 104 serving as the transfer electrode due to the layer structure wherein the polysilicon film 104 formed of an electro-conductive material is directly coated with the silicon nitride film 102 formed of an insulating material having a relatively high dielectric constant. Accordingly, such a gate structure has the advantage of maintaining sufficient potential in the silicon oxide film 106 which is an insulating film.

Furthermore, in general, the outer face of the gate structure 100 at the final stage of the gate manufacturing process is further coated with an insulating film such as a silicon oxide film having a relatively low refractive index. As described above, the upper face, bottom face, and both side faces, of the polysilicon film 104, which is an electro-conductive component, are coated with the silicon nitride film 102 which is an insulating film having an intermediate refractive index between the polysilicon film 104 which is an electro-conductive component and a transparent insulating film formed on the outer face of the gate structure 100.

Such a layer structure has the advantage of suppressing rapid change in the refractive index along the incident light path toward the polysilicon film 104, i.e., the advantage of smooth change in the refractive index therealong, whereby the gate structure 100 suppresses reflection of the incident light for any incident angle.

Thus, the gate structure 100 allows the solid state imaging device, including the photoelectric conversion portion (not shown) within the silicon substrate 108 on which the polysilicon film 104 serving as a gate electrode is formed, to have the advantage of reduced reflection of the incident light for any incident angle as to the photo-receiving face, thereby increasing the sensitivity of the photoelectric conversion portion (not shown) within the substrate.

Note that in general, the silicon nitride film and the silicon oxynitride film have greater relative dielectric constants than that of the silicon oxide film. The silicon nitride film has a relative dielectric constant of around 7, for example. Also, the silicon oxynitride film has a relative dielectric constant of around 3.8 to 7. On the other hand, the silicon oxide film has a relative dielectric constant of around 3.8.

Thus, the gate structure 100 wherein the polysilicon film 104 is employed as a transfer electrode, the silicon nitride film 102 is employed as an insulating coating film, and the silicon oxide film 106 is employed as a gate insulating film, has the advantage of increased charge which can be accumulated in the gate structure 100. Note that the advantage of increasing the accumulated charge depends upon the film thickness of the silicon nitride film 102 formed on the side face of the polysilicon film 104 as described later.

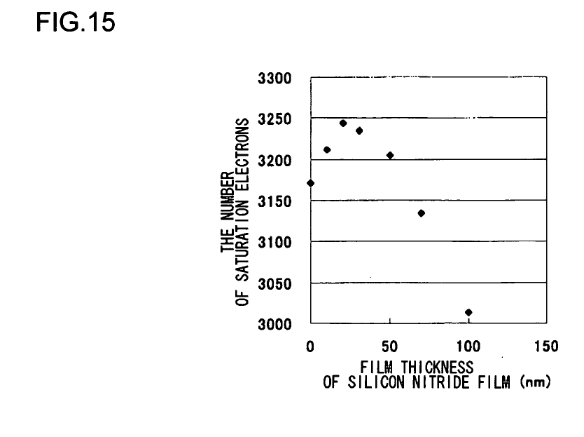

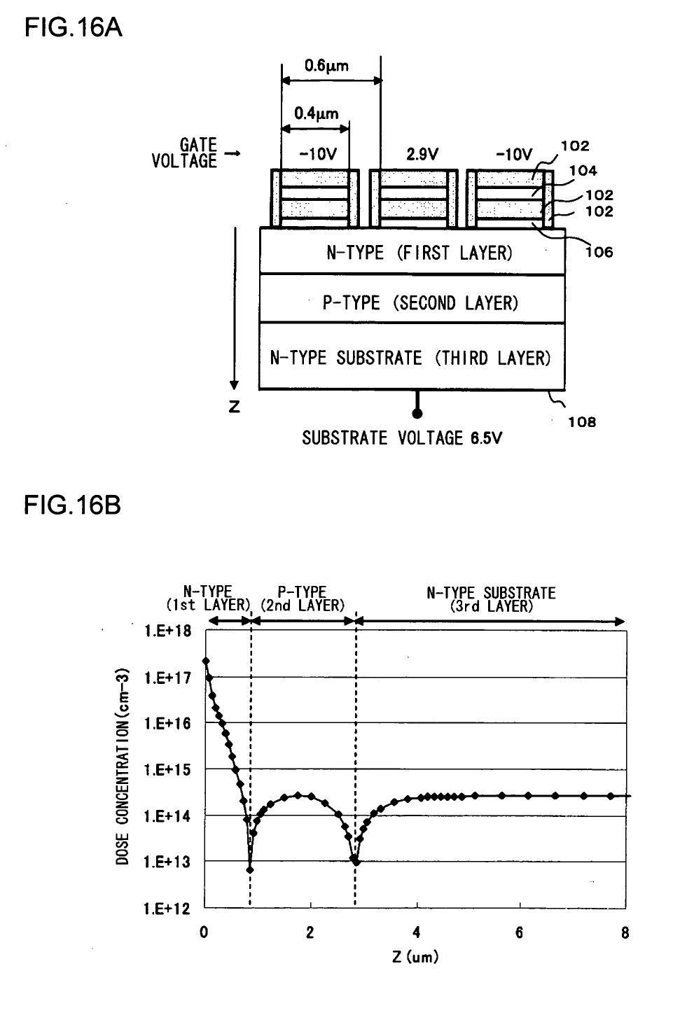

FIG. 15 shows the relation between the film thickness of the silicon nitride film 102 formed on the side face of the polysilicon film 104 and the number of the saturation electrons (Qsat) which can be accumulated and transferred within the silicon substrate 108 underneath the silicon oxide film 106, obtained by simulation. FIGS. 16A and 16B show the conditions of the simulation. This simulation was carried out with the silicon substrate 108 having a three-layer structure of n-layer/p-layer/n-layer as shown in FIG. 16A; each of the layers having a dose concentration shown in FIG. 16B.

Furthermore, as shown in FIG. 16A, the present simulation was carried out with a gate structure wherein three gate electrodes with a width of 0.4 μm are arrayed at a pitch of 0.6 μm. Furthermore, a gate voltage of 2.9 V is applied to the gate electrode at the middle position, and a gate voltage of −10 V is applied to the other gate electrodes. Furthermore, the substrate voltage of 6.5 V is applied to the silicon substrate 108.

Furthermore, the present simulation was carried out with a layer structure formed of: the polysilicon film 104 with a film thickness of 50 nm serving as a gate electrode; the silicon nitride film 102 with a film thickness of 80 nm formed on the bottom face of the polysilicon film 104; and the silicon oxide film 106 with a film thickness of 30 nm. Note that the number of saturation electrons does not depend upon the silicon nitride film 102 formed on the upper face of the polysilicon film 104, and accordingly, the present simulation was carried out without giving consideration to the film thickness thereof.

As shown in FIG. 15, with a gate structure having a film thickness of the silicon nitride film 102 of zero, i.e., a gate structure including no silicon nitride film 102 on the side face of the polysilicon film 104, 3171 saturation electrons are obtained. On the other hand, a gate structure including a silicon nitride film 102 of 20 nm on the side face of the polysilicon film 104 achieves the increased number of saturation electrons to 3244, i.e., an increase of around 2.5%.

On the other hand, with a gate structure wherein the silicon nitride film 102 is formed with a film thickness of 50 nm on the side face of the polysilicon film 104, the number of the saturation electrons is 3205, which is greater than with a gate structure including no silicon nitride film 102 on the side face of the polysilicon film 104, but is smaller than with a gate structure including the silicon nitride film 102 with a film thickness of 20 nm. Furthermore, with a gate structure wherein the silicon nitride film 102 is formed with a film thickness of 70 nm on the side face of the polysilicon film 104, the number of the saturation electrons is 3135, which is smaller than with a gate structure including no silicon nitride film 102 on the side face of the polysilicon film 104. As described above, the silicon nitride film 102 needs to be formed with an optimum film thickness on the side face of the polysilicon film 104 for obtaining as large a number of saturation electrons (Qsat) as possible, which serve as charge that can be accumulated and transferred within the silicon substrate 108 underneath the silicon oxide film 106.

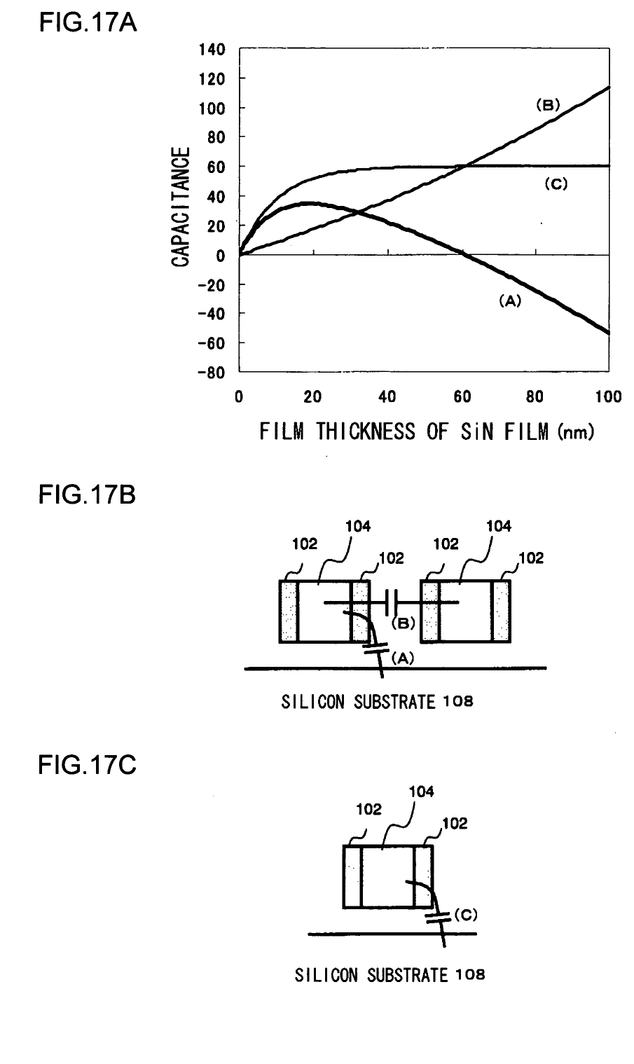

Description will be made below regarding a mechanism of the aforementioned phenomenon. FIG. 17A shows: the relation between the film thickness of the silicon nitride film 102 formed on the side face of the polysilicon film 104 and the electrode-substrate capacitance (A); the relation between the film thickness of the silicon nitride film 102 and the electrode-electrode capacitance (B); and the relation between the film thickness of the silicon nitride film 102 and the electrode-substrate capacitance (C) with a gate structure including the single electrode alone. As shown in FIG. 17B, the electrode-substrate capacitance (A) is the capacitance between the polysilicon film 104 and the silicon substrate 108, and the electrode-electrode capacitance (B) is the capacitance between the polysilicon films 104 serving as gate electrodes adjacent one to another. On the other hand, the electrode-substrate capacitance (C) is the capacitance between the polysilicon film 104 and the silicon substrate 108 with a gate structure including a single gate electrode alone without any adjacent gate electrodes as shown in FIG. 17C. Note that FIG. 17A shows the value which is obtained by subtracting the capacitance calculated under the assumption that no silicon nitride film has been formed on the side face of the polysilicon film 104, from the capacitance calculated for each film thickness of the silicon nitride film 102.

Now, description will be made regarding the relation between the film thickness of the silicon nitride film 102 formed on the side face of the polysilicon film 104 and the capacitance for each film thickness of the silicon nitride film 102, with reference to FIG. 17A. The increased film thickness of the silicon nitride film 102 formed on the side face of the polysilicon film 104 results in monotonous increase of the electrode-substrate capacitance (C) with a gate structure including a single electrode alone. Accordingly, the increased film thickness of the silicon nitride film 102 results in increase of the number of the saturation electrons acting as a charge which can be accumulated and transferred within the silicon substrate 108 underneath the silicon oxide film 106.

However, a gate structure including multiple gate electrodes such as a gate structure included in an actual solid state imaging device exhibits different properties from those of the aforementioned gate structure including a single gate electrode alone, due to the electrode-electrode capacitance (B). With a gate structure including the silicon nitride film having a small film thickness, the electrode-electrode capacitance (B) is small, and accordingly, a strong electric field is applied from the gate electrode to the silicon substrate. Accordingly, in such a range of the silicon nitride film, the increased film thickness of the silicon nitride film 102 leads to increase of the electrode-substrate capacitance (A), resulting in increase of the number of the saturation electrons serving as the charge which can be accumulated and transferred within the silicon substrate 108 underneath the silicon oxide film 106.

However, in a range of a relatively large film thickness of the silicon nitride film, the increased film thickness of the silicon nitride film 102 leads to increase of electrode-electrode capacitance (B), resulting in a strong electric field applied from one gate electrode to the adjacent gate electrode. This leads to the reduced electrode-substrate capacitance (A), resulting in the reduced number of the saturation electrons. Furthermore, let us say that the silicon nitride film is formed with a further increased film thickness t, i.e., a film thickness t in a range of 60 nm≦t. In this case, the electrode-substrate capacitance (A) exhibits a smaller value than with a gate structure including no silicon nitride film 102 formed on the side face of the polysilicon film 104, leading to a smaller number of the saturation electrons, as well.

As described above, with the present embodiment, the silicon nitride film 102 is formed on the side face of the polysilicon film 104 with a film thickness such that the electrode-substrate capacitance (A) is greater than with a gate structure including no silicon nitride film 102 formed thereon, thereby obtaining the increased number of the saturation electrons serving as the charge which can be accumulated and transferred within the silicon substrate 108. That is to say, with the solid state imaging device according to the present embodiment, the silicon nitride film 102 is formed with a film thickness t in a range of 0 nm<t<60 nm on the side face of the polysilicon film 104, thereby obtaining the increased number of the saturation electrons.

Next, description will be made regarding the optical properties of the gate structure.

In general, the silicon nitride film and the silicon oxynitride film exhibit greater refractive indexes than that of the silicon oxide film, as well as the relative dielectric constants thereof. For example, the silicon nitride film exhibits a refractive index of around 2. The silicon oxynitride film exhibits a refractive index of around 1.45 to 2. On the other hand, the silicon oxide film exhibits a refractive index of around 1.45.

Thus, the gate structure 100 wherein the polysilicon film 104 is employed as a transfer electrode, the silicon nitride film 102 is employed as an insulating coating film, and the silicon oxide film 106 is employed as a gate insulating film, has the advantage of suppressing reflection of the incident light.

Specifically, let us say that the solid state imaging device includes a gate structure wherein the silicon oxide film is employed as a transparent upper layer thereof. With such a gate structure wherein the incident light is received by the polysilicon film through the silicon oxide film without passing through other layers, the refractive index rapidly changes from around 1.45 up to around 3.42 along the incident light path. This causes strong reflection of the incident light on the interface between the silicon oxide film and the polysilicon film. In some cases, this reduces the amount of the incident light received by the photoelectric conversion portion (not shown) within the silicon substrate underneath the gate structure, leading to reduced efficiency of photoelectric conversion.

On the other hand, the gate structure 100 including the silicon nitride film 102 with a refractive index of around 2 formed on the bottom face, the upper face, and both side faces, of the polysilicon film 104 has the advantage of smooth change in refractive index of 1.45, 2, and 3.42, along the incident light path, thereby suppressing reflection of the incident light.

As a result, the CCD having the gate structure wherein the incident light is received by the photoelectric conversion portion (not shown) formed underneath the polysilicon film 104 serving as a gate electrode has the advantage of suppressing reflection of the incident light on the interface between the upper layer (not shown) formed of the silicon oxide film and the silicon nitride film 102, the interface between the silicon nitride film 102 and the polysilicon film 104, and so forth, thereby preventing reduction of the sensitivity of the photoelectric conversion portion (not shown).

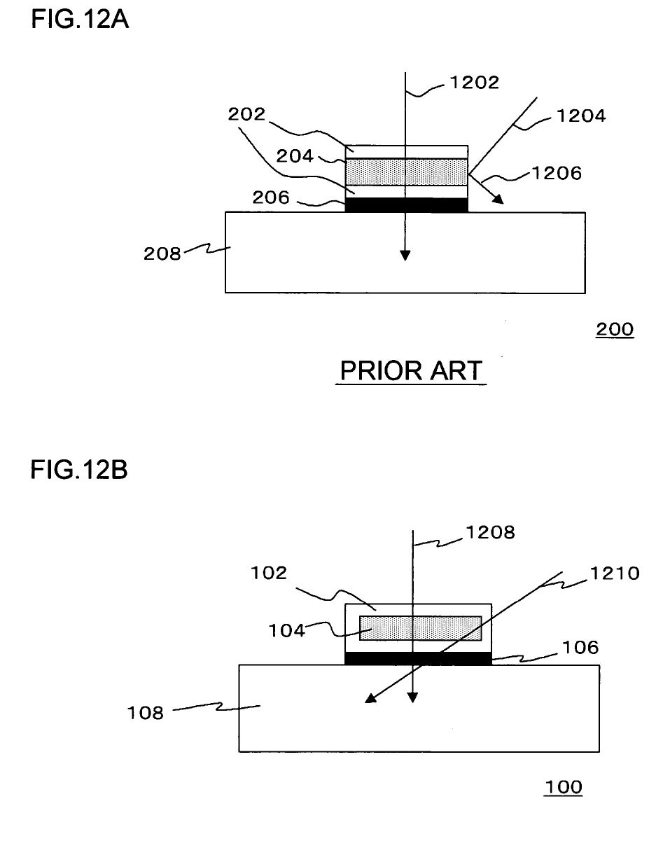

FIGS. 12A and 12B are cross-sectional diagrams which show reflection of the incident light with a gate structure of a conventional solid state imaging device as a comparative example, and reflection thereof with a gate structure of the solid state imaging device according to the present embodiment, respectively.

Specifically, with the gate structure 200 of the conventional solid state imaging device, the incident light 1202 with an incident angle of 90° passes through the upper layer formed of a silicon oxide film (not shown) and the silicon nitride film 202, and is received by the polysilicon film 204, as shown in FIG. 12A. In this case, the refractive index exhibits smooth change of 1.45, 2, and 3.42, along the path of the incident light 1202, thereby suppressing reflection of the incident light on the surface of the polysilicon film 204. Thus, the incident light 1202 with an incident angle of 90° passes through the gate structure 200 in the direction indicated by the arrow shown in the drawing, reaching the photoelectric conversion portion (not shown) formed in the layer underneath the gate structure.

On the other hand, with the gate structure 200 of the conventional solid state imaging device, the incident light 1204 with a slant incident angle is received by the polysilicon film 204 through the silicon oxide film (not shown) without passing through other layers, as shown in FIG. 12A. In this case, the reflective index exhibits rapid change of around 1.45 to around 3.42, leading to strong reflection wherein most of the incident light 1204 is reflected and scattered as the reflected light 1206 on the surface of the polysilicon film 204. Accordingly, only a small part of the incident light 1204 with a slant incident angle passes through the gate structure 200, leading to a reduced amount of the incident light received by the photoelectric conversion portion (not shown) formed underneath the gate structure.

Accordingly, in some cases, the gate structure 200 of the conventional solid state imaging device has the disadvantage of the insufficient sensitivity of the photoelectric conversion portion (not shown) formed as a lower layer of the gate structure 200.

Note that, with the gate structure 100 of the solid state imaging device according to the present embodiment, the incident light 1208 with an incident angle of 90° passes through the gate structure as indicated by the arrow in FIG. 12B in the same way as with the gate structure 200 of the conventional solid state imaging device, and reaches the photoelectric conversion portion (not shown) formed as a lower layer thereof.

On the other hand, with the gate structure 100 of the solid state imaging device according to the present embodiment, the incident light 1210 with a slant incident angle passes through the upper layer formed of a silicon oxide film (not shown) and the silicon nitride film 102, and is received by the polysilicon film 104, as shown in FIG. 12B. In this case, the refractive index exhibits smooth change thereof, e.g., 1.45, 2, and 3.42, along the incident light path, thereby suppressing reflection of the incident light on the surface of the polysilicon film 104. Thus, most of the incident light 1210 with a slant incident angle passes through the gate structure 100 in the direction indicated by the arrow in the drawing, reaching the photoelectric conversion portion (not shown) formed as a lower layer of the gate structure 100.

Thus, the gate structure 100 of the solid state imaging device according to the present embodiment has the advantage of the improved sensitivity of the photoelectric conversion portion (not shown) formed as a lower layer of the gate structure 100, as compared with the gate structure 200 of the conventional solid state imaging device.

### Second Embodiment

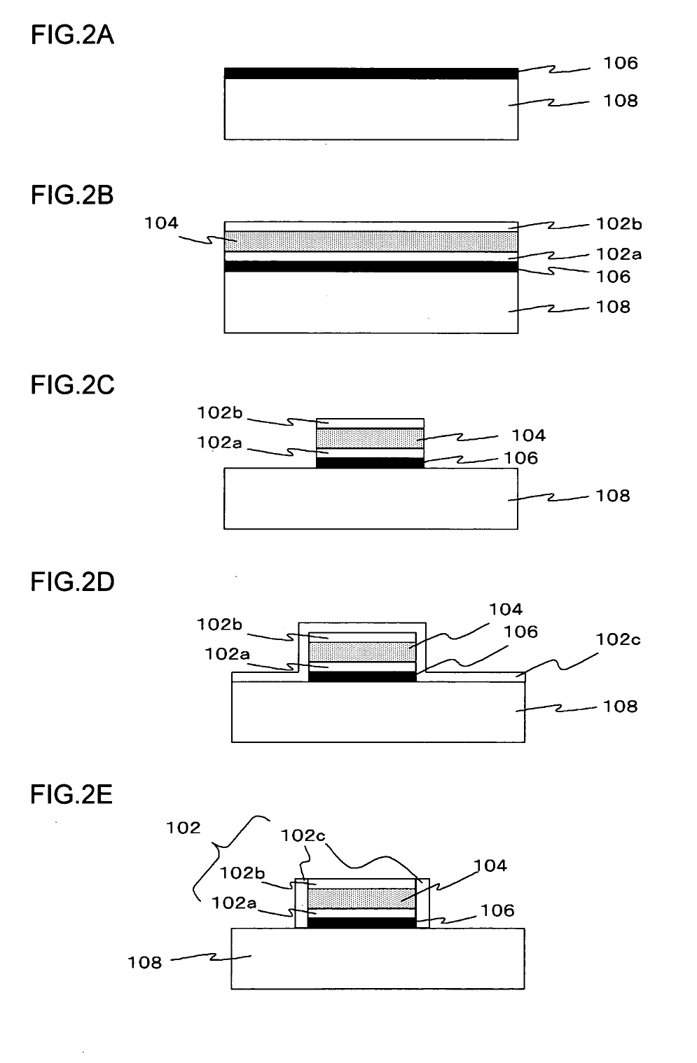

FIGS. 2A through 2E are a series of cross-sectional diagrams, which shows an example of the gate structure of the solid state imaging device according to the present embodiment for each manufacturing step. The gate structure of the solid state imaging device according to the present embodiment may be formed with a manufacturing method according to the present embodiment shown in FIG. 2, wherein, following formation of the three-layer structure including the transfer electrodes, side-wall formation is performed.

Specifically, as shown in FIG. 2A, first, the silicon oxide film 106 is layered on the silicon substrate 108. Subsequently, as shown in FIG. 2B, the silicon nitride film 102a, the polysilicon film 104, and the silicon nitride film 102b, are layered on the silicon oxide film 106 in that order.

Subsequently, a resist film (not shown) is formed on the silicon nitride film 102b, and patterning of the resist film is performed. Then, as shown in FIG. 2C, etching of the silicon oxide film 106, the silicon nitride film 102a, the polysilicon film 104, and the silicon nitride film 102b, is performed with the patterned resist film as a mask, whereby patterning thereof is performed with predetermined widths. Note that the resist film is removed after etching.

Subsequently, as shown in FIG. 2D, a silicon nitride film 102c is layered on the upper face of the silicon substrate 108 and the silicon nitride film 102b, and both side faces of the multi-layer structure formed of the silicon oxide film 106, the silicon nitride film 102a, the polysilicon film 104, and the silicon nitride film 102b.

Subsequently, a resist film (not shown) is formed on the silicon nitride film 102c, and patterning of the resist film is performed. Then, as shown in FIG. 2E, etching is performed such that the silicon nitride film 102c remains only on the side faces of the multi-layer structure formed of the silicon oxide film 106, the silicon nitride film 102a, the polysilicon film 104, and the silicon nitride film 102b while the silicon nitride film 102c formed on the silicon substrate 108 and the upper face of the silicon nitride film 102b is removed, whereby the remaining silicon nitride film 102c serves as a side wall for the multi-layer structure.

With such a manufacturing process, the gate structure of the solid state imaging device according to the present embodiment is obtained. With such a gate structure, the bottom face, upper face, and both side faces, of the polysilicon film 104 are coated with the silicon nitride film 102.

Note that, while the silicon nitride film 102 is formed of multiple films of the silicon nitride film 102a, the silicon nitride film 102b, and the silicon nitride film 102c, these films are formed of the same material. This allows strong bonding of the multiple films. Such strong bonding of the multiple films improves the advantage of preventing infiltration of an etchant from a gap in the multi-layer structure. This suppresses erosion of the polysilicon film, thereby improving the advantage of suppressing increase of the resistance of the transfer electrode.

Furthermore, the silicon nitride film 102 has a relatively high relative dielectric constant of around 7, thereby increasing the charge which can be accumulated around the polysilicon film 104. Thus, the solid state imaging device including such a gate structure has the advantage of increased charge which can be accumulated and transferred.

Furthermore, the silicon nitride film 102 has a refractive index of around 2, which is lower than the refractive index of the polysilicon film 104 of 3.42. This allows smooth change in the refractive index along the incident light path; the incident light passing through the polysilicon film 104. Thus, such a gate structure has the advantage of suppressing reflection of the incident light with slant incident angle.

### Third Embodiment

FIG. 9 is a cross-sectional diagram which shows an modification of a gate structure of a solid state imaging device according to the present embodiment. A gate structure 400 of the solid state imaging device according to the present embodiment includes a silicon nitride film 102a formed on the silicon substrate 108, the polysilicon film 104 formed on the silicon nitride film 102a, and a silicon nitride film 102d for coating the upper face and both side faces of the polysilicon film 104.

With such a structure, the bottom face, the upper face, and both side faces of the polysilicon film 104 are coated with the silicon nitride films 102a and 102d, as well. Thus, such a gate structure prevents erosion of both side faces of the polysilicon film 104 due to infiltration of an etchant at the time of etching processing for other components. Thus, such a gate structure suppresses increase of the resistance of the polysilicon film 104.

Furthermore, the silicon nitride films 102a and 102d have a relatively high relative dielectric constant of around 7, thereby increasing the charge which can be accumulated around the polysilicon film 104. Thus, the solid state imaging device including such a gate structure has the advantage of increased charge which can be accumulated and transferred.

Furthermore, the silicon nitride films 102a and 102d have a refractive index of around 2, which is lower than the refractive index of the polysilicon film 104 of 3.42. This allows smooth change in the refractive index along the incident light path; the incident light passing through the polysilicon film 104. Thus, such a gate structure has the advantage of suppressing reflection of the incident light with incident angle.

### Fourth Embodiment

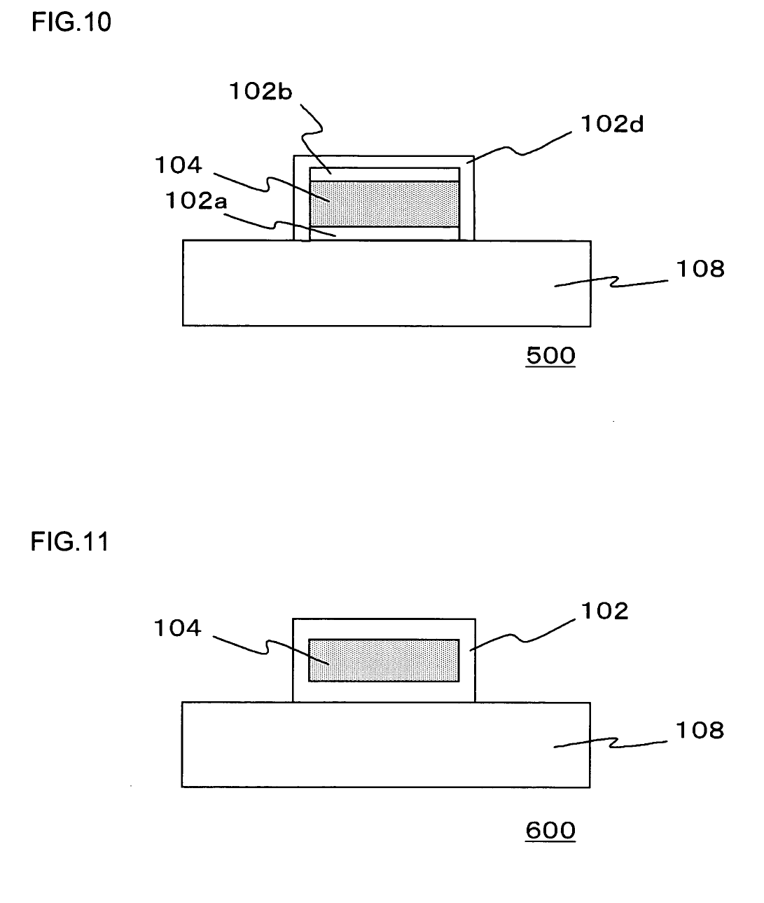

FIG. 10 is a cross-sectional diagram which shows a modification of a gate structure of a solid state imaging device according to the present embodiment. A gate structure 500 of the solid state imaging device according to the present embodiment includes a silicon nitride film 102a formed on the silicon substrate 108, the polysilicon film 104 formed on the silicon nitride film 102a, the silicon nitride film 102b formed on the upper face of the polysilicon film 104, and the silicon nitride film 102d for coating the upper face of the silicon nitride film 102b and both side faces of a multi-layer structure formed of the silicon nitride film 102a, the polysilicon film 104, and the silicon nitride film 102b.

With such a structure, the bottom face, the upper face, and both side faces of the polysilicon film 104 are coated with the silicon nitride films 102a, 102b, and 102d, as well. Thus, such a gate structure prevents erosion of both side faces of the polysilicon film 104 due to infiltration of an etchant at the time of etching processing for other components. Thus, such a gate structure suppresses increase of the resistance of the polysilicon film 104.

Furthermore, the silicon nitride films 102a, 102b, and 102d have a relatively high relative dielectric constant of around 7, thereby increasing the charge which can be accumulated around the polysilicon film 104. Thus, the solid state imaging device including such a gate structure has the advantage of increased charge which can be accumulated and transferred.

Furthermore, the silicon nitride films 102a, 102b, and 102d have a refractive index of around 2, which is lower than the refractive index of the polysilicon film 104 of 3.42. This allows smooth change in the refractive index along the incident light path; the incident light passing through the polysilicon film 104. Thus, such a gate structure has the advantage of suppressing reflection of the incident light.

### Fifth Embodiment

FIG. 11 is a cross-sectional diagram which shows an modification of a gate structure of a solid state imaging device according to the present embodiment. A gate structure 600 of the solid state imaging device according to the present embodiment includes the polysilicon film 104 formed above the silicon substrate 108, and the silicon nitride film 102 for coating the bottom face, the upper face, and both side faces, of the polysilicon film 104.

With such a structure, the bottom face, the upper face, and both side faces of the polysilicon film 104 are coated with the silicon nitride films 102, as well. Thus, such a gate structure prevents erosion of both side faces of the polysilicon film 104 due to infiltration of an etchant at the time of etching processing for other components. Thus, such a gate structure suppresses increase of the resistance of the polysilicon film 104.

Furthermore, the silicon nitride film 102 has a relatively high relative dielectric constant of around 7, thereby increasing the charge which can be accumulated around the polysilicon film 104. Thus, the solid state imaging device including such a gate structure has the advantage of increased charge which can be accumulated and transferred.

Furthermore, the silicon nitride film 102 has a refractive index of around 2, which is lower than the refractive index of the polysilicon film 104 of 3.42. This allows smooth change in the refractive index along the incident light path; the incident light passing through the polysilicon film 104. Thus, such a gate structure has the advantage of suppressing reflection of the incident light.

### Sixth Embodiment

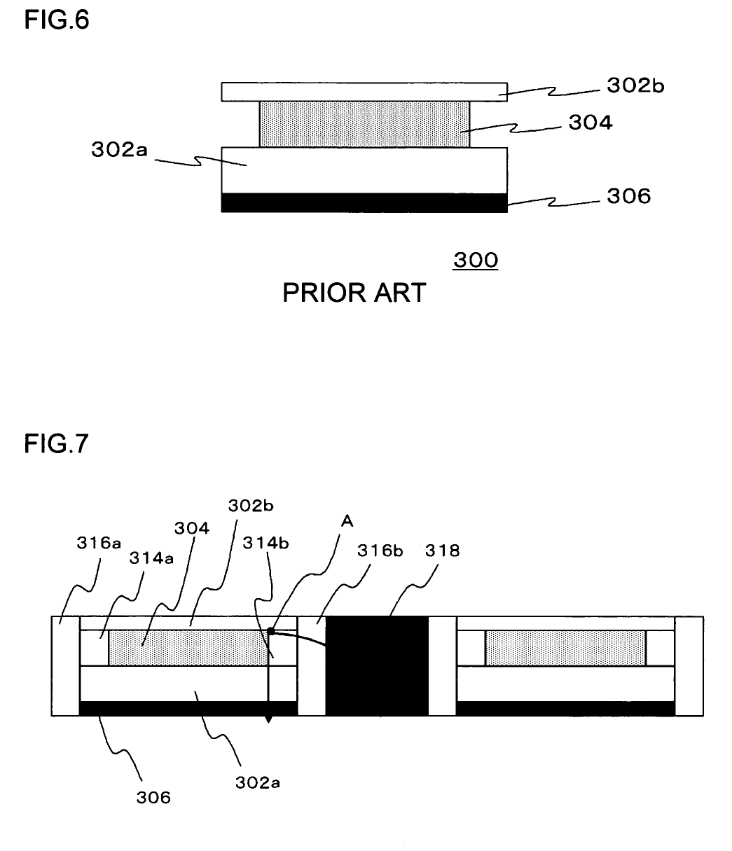

FIG. 6 is an enlarged cross-sectional diagram which shows the problems of a gate structure of a conventional solid state imaging device. A gate structure 300 of the conventional solid state imaging device includes a semiconductor substrate (not shown), a silicon oxide film 306 formed on the semiconductor substrate, a silicon nitride film 302a formed on the silicon oxide film 306, a polysilicon film 304 formed on the silicon nitride film 302a, and a silicon nitride film 302b formed on the polysilicon film 304.

As described above, the gate structure of the conventional solid state imaging device shown in FIG. 3 has problems of erosion of both side faces of the polysilicon film 304 which is an electro-conductive component, edge roughness on both side faces of the polysilicon film 304, and so forth, due to cleansing, surface treatment, and so forth, as shown in FIG. 6.

However, an arrangement may be made wherein the gate structure 300 having the polysilicon film 304 with both side faces eroded is coated with an insulating material such as a silicon nitride film. Such a structure has the advantage of increasing the charge which can be accumulated, and the advantage of suppressing reflection of the incident light, due to the dielectric constant and the refractive index thereof. Description will be made below regarding these advantages with reference to specific examples.

Description will now be made regarding an example wherein a silicon nitride film is embedded in the eroded portion of the polysilicon film 304, and an example wherein a silicon oxide film is embedded in the eroded portion of the polysilicon film 304. Note that the potential on the upper face of the polysilicon film 304 was calculated, and evaluation of transparency thereof was made with regard to the incident light, for each example.

FIG. 7 is a cross-sectional diagram for describing an arrangement wherein SiN is embedded in the gap in the gate structure of the conventional solid state imaging device, which has occurred due to erosion.

With such an arrangement, the gaps occurring on both side faces of the polysilicon film 304 are covered with silicon nitride films 314a and 314b. Furthermore, both side faces of the gate structure are coated with silicon nitride films 316a and 316b. Furthermore, the side face of the silicon nitride film 316b is coated with a silicon oxide film 318.

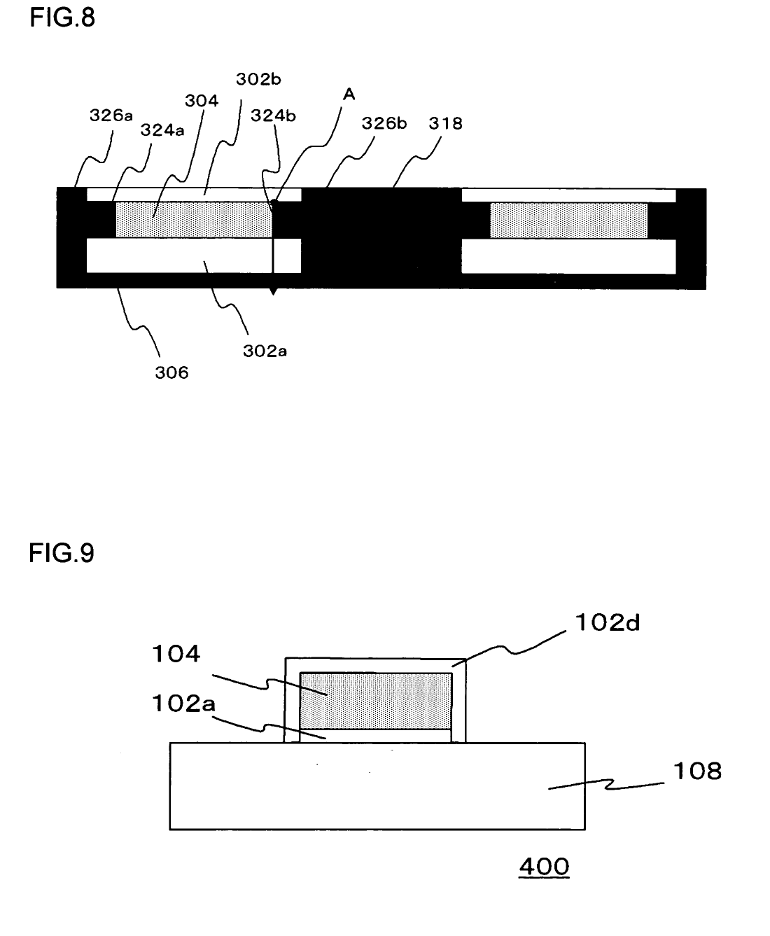

FIG. 8 is a cross-sectional diagram for describing an arrangement wherein SiO₂ is embedded in the gap in the gate structure of the conventional solid state imaging device, which has occurred due to erosion.

With such an arrangement, the gaps occurring on both side faces of the polysilicon film 304 are covered with silicon oxide films 324a and 324b. Furthermore, both side faces of the gate structure are coated with silicon oxide films 326a and 326b. Furthermore, the side face of the silicon oxide film 326b is coated with a silicon oxide film 318.

The potential on the upper face of the polysilicon film 304 was calculated for each example by calculating the potential drop using the Poisson equation, according simply to the lines of electric force from the gate edge alone. Note that, while more detailed evaluation requires device simulation, the calculation results thus obtained serve as a sufficient estimation.

Calculation was made using parameters as follows. That is to say, calculation was made with a gate structure formed of: the silicon nitride film 302b with a thickness of 20 nm; the polysilicon film 304 with a thickness of 60 nm; the silicon nitride film 302a with a thickness of 80 nm; the silicon oxide film 306 with a thickness of 30 nm; and the silicon nitride film 316b with a width of 50 nm formed on the side walls of the gate structure, with the polysilicon film 304 having been eroded by a width of 50 nm.

Furthermore, simulation was carried out under the conditions that a voltage of 10 V is applied to the polysilicon film 304 serving as a gate electrode while applying a voltage of zero to the semiconductor substrate (not shown) having a dose concentration of 1×10¹¹ cm^{-3.}

With simulation regarding the gate structure wherein SiN has been embedded into the gaps therein, the voltage denoted by A in the drawing was calculated to be 4.98 V. On the other hand, with simulation regarding the gate structure wherein SiO₂ has been embedded into the gaps therein, the voltage denoted by A in the drawing was calculated to be 3.76 V. Furthermore, with simulation regarding the gate structure wherein SiN has been embedded into the gaps therein, the depletion layer width was calculated to be 1.15 μm, and the local accumulated charge density at A was calculated to be 5750 electrons/μm². On the other hand, with simulation regarding the gate structure wherein SiO₂ has been embedded into the gaps therein, the depletion layer width was calculated to be 1 μm, and the local accumulated charge density at A was calculated to be 5000 electrons/μm². That it to say, the gate structure wherein SiN has been embedded into the gaps therein has the advantage of increase of the local accumulated charge density of around 15%.

On the other hand, the gate structure as shown in FIG. 7 wherein the silicon nitride film 302a is formed as the lower layer of the electrode formed of the polysilicon film 304 has the advantage of the stable and increased gate capacitance. Thus, such a gate structure wherein the silicon oxide film 306, the silicon nitride film 302a, and the polysilicon film 304, are formed on the silicon substrate (not shown) in that order, enables the stable and increased gate capacitance.

Furthermore, the structure shown in FIG. 8 has a problem of edge roughness of both side faces of the polysilicon film 304 due to erosion thereof by etching, often leading to a problem of irregular reflection of the incident light.

On the other hand, with the structure shown in FIG. 7, the silicon nitride films 314a and 314b, which have a relatively higher refractive index than that of the silicon oxide films 324a and 324b, are embedded into the gaps in both side faces of the polysilicon film 304.

With such a structure, the difference in the refractive index between the polysilicon film 304 and each of the silicon nitride films 314a and 314b is relatively small, thereby suppressing irregular reflection of the light. That is to say, the structure shown in FIG. 7 has the advantage of suppressing irregular reflection of the light as compared with the structure shown in FIG. 8.

Furthermore, the structure shown in FIG. 7 wherein the silicon nitride film 302b is layered on the electrode component formed of the polysilicon film 304, has the advantage that etching of the polysilicon film 304 may be performed with the silicon nitride film 302b, which is the upper layer, as a hard mask for etching processing, at the time of patterning of these layers at the same time.

Such a manufacturing process improves the uniformity of the width of the polysilicon film 304 subjected to etching, thereby effectively suppressing the edge roughness. Thus, the structure shown in FIG. 7 has the advantage of suppressing irregular reflection of the light as compared with the structure shown in FIG. 8, from this perspective.

Furthermore, the structure shown in FIG. 7 includes the multiple transfer portions each of which are formed of: the polysilicon film 304; the silicon nitride film 302b serving as the upper layer of the polysilicon film 304; the silicon nitride film 302a serving as the lower layer thereof; and the silicon nitride films 314a and 314b serving as the side walls thereof. Furthermore, the silicon nitride films 316a and 316b are formed on the side faces of each transfer portion. Furthermore, an insulating film formed of the silicon oxide film 318 having a lower relative dielectric constant than that of the silicon nitride film is further formed on the side faces of the aforementioned structure thus formed. That is to say, these multiple transfer portions are arrayed with the silicon oxide film, which has a lower relative dielectric constant than that of the silicon nitride film, introduced therebetween.

Such a structure including the multiple transfer portions improves the charge transfer efficiency. Furthermore, the multiple transfer portions are arrayed with the silicon oxide film serving as an insulating film, which has a lower refractive index than that of the silicon nitride film serving as an insulating coating film, introduced therebetween, thereby suppressing reflection of the incident light at slant incident angle. An arrangement wherein the photoelectric conversion portions are formed underneath the transfer portions may employ such a structure, thereby improving the sensitivity of each photoelectric conversion portion, in the same way.

### Seventh Embodiment

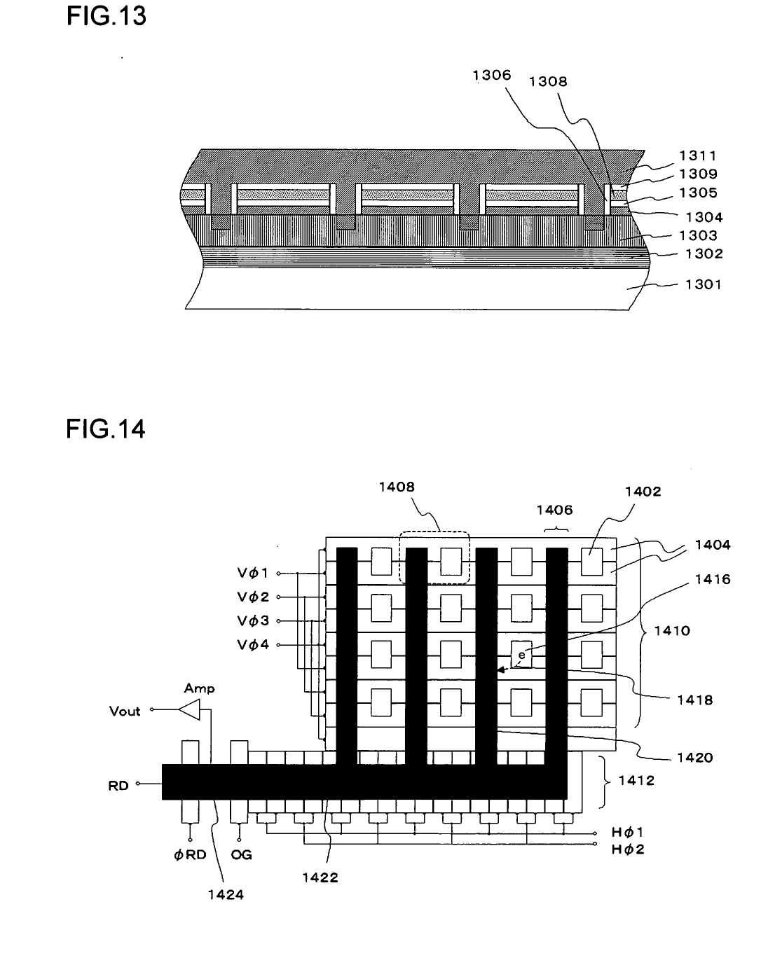

FIG. 13 is a cross-sectional diagram which shows the transfer portions and the photoelectric conversion portions of the solid state imaging device according to the present embodiment. More specifically, FIG. 13 is a longitudinal cross-sectional configuration diagram which shows the solid state imaging device, taken along the line in the charge-transfer direction. Note that, as the solid state imaging device according to the present embodiment, a so-called single-layer electrode CCD is employed, wherein the transfer electrodes, each of which are a component of the vertical charge coupled device, are formed by patterning a single polysilicon film. Furthermore, a p-type well region 1302 is formed on the upper face of an n-type silicon substrate 1301. Furthermore, an n-type CCD channel region 1303 is formed on the upper face of the p-type well region 1302.

Here, the n-type silicon substrate 1301 has a phosphorus concentration serving as a dose concentration of around 10¹³ cm⁻³ through 10¹⁵ cm⁻³. The p-type well region 1302 is formed with a depth of around 1 μm through 5 μm, and has a boron concentration serving as a dose concentration of around 10¹⁵ cm⁻³ through 10¹⁷ cm⁻³. On the other hand, the n-type CCD channel region 1303 is formed with a depth of around 0.1 μm through 2 μm, and has a phosphorus concentration or an arsenic concentration serving as a dose concentration of around 10¹⁶ cm⁻³ through 10¹⁷ cm^{-3.}

The n-type CCD channel region 1303 is divided into multiple regions in the vertical direction by a p⁺-type channel blocking region 1310. The p⁺-type channel blocking region 1310 is formed with a depth of around 1 μm through 4 μm, and has a boron concentration serving as a dose concentration of around 10¹⁷ cm⁻³ through 10¹⁹ cm⁻³, for example. Furthermore, the multi-layer structure formed of: a silicon oxide film 1304; a silicon nitride film 1305; a polysilicon film 1308; and a silicon nitride film 1309, is formed on the upper face of the n-type CCD channel region 1303. Furthermore, a silicon nitride film 1306 is formed on both side faces of the multi-layer structure.

Furthermore, a silicon oxide film 1311 is formed so as to cover the upper face of the multi-layer structure. Furthermore, the multi-layer structure is divided into multiple portions with the region above the p⁺-type channel blocking region 1310 as a boundary. The gate electrode structure including the multi-layer structure may employ the structure described in the aforementioned embodiments.

With such a structure, the polysilicon film is covered with an insulating material such as a silicon nitride film, thereby suppressing irregularities in the resistance of each electrode, and thereby increasing the charge which can be accumulated.

Furthermore, the aforementioned structure includes multiple transfer electrodes, thereby improving charge transfer efficiency. Furthermore, with the present embodiment, each transfer electrode is coated with the silicon nitride film having a greater refractive index than that of the silicon oxide film for covering the upper face thereof, thereby suppressing reflection of the incident light with slant incident angle; the incident light being received by the transfer portion. Such a structure may be employed in an arrangement wherein a photoelectric conversion portion is formed at a lower portion of each transfer portion, thereby improving the sensitivity of each photoelectric conversion portion with regard to the incident light.

FIG. 14 is an overall plan view of the solid state imaging device according to the present embodiment. Note that, in general, an interline transfer CCD is employed as the solid state imaging device according to the present embodiment.

The solid state imaging device according to the present embodiment includes an imaging region 1410, vertical transfer electrodes 1406, and horizontal transfer electrodes 1412. Furthermore, photodiodes 1402 are arrayed on the imaging region 1410 along each of the vertical transfer electrodes 1406. Each portion formed of the single photodiode 1402 and a part of the vertical transfer electrode 1406 adjacent to the photodiode 1402 serves as a pixel 1408. Each photodiode 1402 is connected to the corresponding vertical transfer electrode 1406 with an electrode 1404.

The charge 1416 generated by photoelectric conversion and accumulated in each photodiode 1402 transferred through the electrode 1404 is further transferred to the vertical transfer electrode 1406 through a readout transfer path 1418 as shown in the drawing. The charge 1416 thus read out and transferred is further transferred to the horizontal transfer electrode 1412 through a vertical transfer path 1420 in the vertical transfer electrode 1406 as shown in the drawing. Subsequently, the charge 1416 is transferred through a horizontal transfer path 1422 in the horizontal transfer electrode 1412 as shown in the drawing, whereby the charge 1416 is detected by a charge detector 1424 formed at the end of the horizontal transfer electrode 1412.

The gate electrode structure described in the aforementioned embodiments may be employed as the horizontal transfer electrode 1406 of the solid state imaging device according to the present embodiment. With such a structure, the polysilicon film forming the vertical transfer electrode 1406 is covered with an insulating material such as a silicon nitride film, thereby suppressing irregularities in the resistance of the electrode, as well as increasing the charge which can be accumulated.

Furthermore, such a structure includes the multiple vertical transfer electrodes 1406, thereby improving the charge transfer efficiency. Furthermore, with the present embodiment, each vertical transfer electrode 1406 is covered with the silicon nitride film having a greater refractive index than that of the silicon oxide film for covering the upper portion thereof, thereby suppressing reflection of the incident light with slant incident angle; the incident light being received by the transfer portion. Such a structure may be employed in an arrangement wherein a photoelectric conversion portion is formed at a lower portion of each transfer portion, thereby improving the sensitivity of each photoelectric conversion portion with regard to the incident light.

As described above, description has been made regarding the present invention with reference to the aforementioned embodiments. The above-described embodiments have been described for exemplary purposes only, and are by no means intended to be interpreted restrictively. Rather, it can be readily conceived by those skilled in this art that various modifications may be made by making various combinations of the aforementioned components or the aforementioned processing, which are also encompassed in the technical scope of the present invention.

For example, description has been made in the aforementioned embodiment regarding an arrangement wherein such a structure according to the aforementioned embodiments is applied to the transfer electrode formed at a position within the solid state imaging device such as a CCD and so forth, for receiving the incident light. However, the present invention is not intended to be restricted to the aforementioned arrangement. Rather, an arrangement may be made wherein such a structure according to the aforementioned embodiments is applied to the transfer electrode formed at a position within the solid state imaging device such as a CCD and so forth, having no function for receiving the incident light. Such an arrangement wherein the bottom face, the upper face, and both side faces, of the transfer electrode, are coated with an insulating coating film, has the advantage of suppressing erosion of both side faces of the transfer electrode due to an etchant at the time of etching processing. This suppresses increase of the resistance of the transfer electrode.

Furthermore, the insulating coating film such as a silicon nitride film and so forth has a relatively high relative dielectric constant, thereby increasing the charge which can be accumulated around the transfer electrode. This results in the advantage of increased charge which can be accumulated and transferred in the solid state imaging device.

Also, description has been made in the aforementioned embodiment regarding an arrangement wherein such a gate structure according to the aforementioned embodiments is applied to an interline transfer CCD wherein the incident light passes through the layer structure, and a charge is generated by photoelectric conversion within the semiconductor substrate. However, the present invention is not restricted to the aforementioned arrangement. Rather, the gate structure according to the aforementioned embodiments may be applied to a frame transfer CCD, a full-frame CCD, and so forth, as well.

1. A solid state imaging device comprising:
photoelectric conversion portions for performing photoelectric conversion; and
transfer portions for transferring signal charge occurring at said photoelectric conversion portion,
wherein each of said transfer portion include a transfer electrode, and an insulating coating film formed of a material having a higher relative dielectric constant than that of silicon oxide, for coating the bottom face, the upper face, and both side faces, of said transfer electrode.

2. A solid state imaging device according to claim 1, wherein said insulating coating film has a refractive index which is greater than that of silicon oxide, and smaller than that of said transfer electrode.

3. A solid state imaging device according to claim 1, wherein said insulating coating film is formed of a material containing silicon nitride.

4. A solid state imaging device according to claim 2, wherein said insulating coating film is formed of a material containing silicon nitride.

5. A solid state imaging device according to claim 1, wherein said insulating coating film is formed of a material containing silicon oxynitride.

6. A solid state imaging device according to claim 2, wherein said insulating coating film is formed of a material containing silicon oxynitride.

7. A solid state imaging device according to claim 1, wherein said transfer electrode is formed of a material containing polysilicon.

8. A solid state imaging device according to claim 1, wherein said insulating coating film is formed with a film thickness t in a range of 0 nm<t<60 nm, on both side faces of said transfer electrode.

9. A solid state imaging device according to claim 2, wherein said insulating coating film is formed with a film thickness t in a range of 0 nm<t<60 nm, on both side faces of said transfer electrode.

10. A solid state imaging device according to claim 3, wherein said insulating coating film is formed with a film thickness t in a range of 0 nm<t<60 nm, on both side faces of said transfer electrode.

11. A solid state imaging device according to claim 5, wherein said insulating coating film is formed with a film thickness t in a range of 0 nm<t<60 nm, on both side faces of said transfer electrode.

12. A solid state imaging device according to claim 1, wherein said plurality of transfer portions are arrayed in parallel, with an insulating film, which has a lower relative dielectric constant than that of said insulating coating film, introduced therebetween.

13. A solid state imaging device according to claim 2, wherein said plurality of transfer portions are arrayed in parallel, with an insulating film, which has a lower relative dielectric constant than that of said insulating coating film, introduced therebetween.

14. A solid state imaging device according to claim 3, wherein said plurality of transfer portions are arrayed in parallel, with an insulating film, which has a lower relative dielectric constant than that of said insulating coating film, introduced therebetween.

15. A solid state imaging device according to claim 5, wherein said plurality of transfer portions are arrayed in parallel, with an insulating film, which has a lower relative dielectric constant than that of said insulating coating film, introduced therebetween.

16. A solid state imaging device according to claim 1, wherein said plurality of transfer portions are arrayed in parallel, with an insulating film, which has a lower refractive index than that of said insulating coating film, introduced therebetween.

17. A solid state imaging device according to claim 2, wherein said plurality of transfer portions are arrayed in parallel, with an insulating film, which has a lower refractive index than that of said insulating coating film, introduced therebetween.

18. A solid state imaging device according to claim 11, wherein said plurality of transfer portions are arrayed with an insulating film, which has a lower refractive index than that of said insulating coating film, introduced therebetween.

19. A solid state imaging device according to claim 12, wherein said plurality of transfer portions are arrayed with an insulating film, which has a lower refractive index than that of said insulating coating film, introduced therebetween.

20. A manufacturing method for a solid state imaging device comprising:
a step wherein a first insulating coating film formed of a material having a higher relative dielectric constant than that of silicon oxide, an electro-conductive film, and a second insulating coating film formed of a material having a higher relative dielectric constant than that of silicon oxide, are layered in that order on the upper face of a semiconductor substrate, thereby forming a multi-layer structure;
a step for performing selective etching of said multi-layer structure with a predetermined width;
a step for forming a third insulating coating film formed of a material having a higher relative dielectric constant than that of silicon oxide, so as to cover the upper face, both side faces, of said multi-layer structure, and the upper face of said semiconductor substrate; and
a step for etching said third insulating coating film such that both side faces of said multi-layer structure are covered with said third insulating coating film thus patterned.
